(19) United States
(12) Patent Application Publication
(10) Pub. No.: US 2022/0336422 A1
(43) Pub. Date: Oct. 20, 2022

(54) Display Substrate and Display Device

(71) Applicant: CHONGQING KONKA PHOTOELECTRIC TECHNOLOGY RESEARCH INSTITUTE CO., LTD., Chongqing (CN)

(72) Inventors: Shan-fu YUAN, Chongqing (CN); Yi XIANG, Chongqing (CN)

(21) Appl. No.: 17/264,862

(22) PCT Filed: Dec. 30, 2019
(86) PCT No.: PCT/CN2019/129990

§ 371 Date: Feb. 1, 2021

(51) Int. Cl. H01L 25/075; G02B 27/30; G02B 5/04; G02B 5/02; G02B 5/26; H01L 33/58

(52) U.S. Cl. CPC H01L 25/0753; G02B 27/30; G02B 5/045; G02B 5/0278; G02B 5/26; H01L 33/58; H01L 2933/0091

(57) ABSTRACT

The present invention provides a display substrate and a display device. The display substrate comprises a backplate and a plurality of pixel units; each pixel unit of the pixel units comprises a white light LED; a collimating lens configured to collimate a white light beam; a prism layer configured to reflect the white light beam to generate monochromatic lights of different colors in a first direction and a second direction; transmittance controllers configured to modulate the transmittance of monochromatic lights of different colors; and scattering layers configured to scatter monochromatic lights of different colors. In the present application, achieving the double-sided display of a Micro-LED display device, increasing the functionality and interestingness of the display device, and reducing the workload for mass transfer of the Micro-LED display device and the complexity of circuit arrangements of the display device.

### TECHNICAL FIELD

The present invention relates to the field of semiconductor optoelectronic technology, and in particular, to a display substrate and a display device.

### BACKGROUND

The Micro-LED display device has the advantages in terms of good stability, service life, and operating temperature, and also retains the merits of the LED of low power consumption, color saturation, quick response, high contrast, etc. The Micro-LED has higher brightness and lower power consumption, and therefore the Micro-LED display device has great application prospects.

Schematic diagrams showing the structures of the display substrate of a current Micro-LED display device are shown in FIG. 1 and FIG. 2. The display substrate of the current Micro-LED display device consists of a backplate and a plurality of pixel units provided on the backplate, and the pixel units each include a red light LED, a green light LED and a blue light LED which are arranged sequentially. In order to save costs, there is also a display substrate of the Micro-LED display device as shown in FIG. 3. In the display substrate as shown in FIG. 3, the red light LED, the green light LED and the blue light LED which are arranged sequentially in each pixel unit as shown in FIG. 1 and FIG. 2 are changed into three low-price blue light LEDs, and a wavelength conversion layer is mounted in a light emergent direction of the LEDs, so that the pixel unit can emit lights of RGB three colors. All the Micro-LED display devices described above can only achieve the single-sided display, and three LED chips need to be mounted on the backplate to form a pixel unit, and therefore the workload for mass transfer of the Micro-LED display device is huge, and the circuit arrangements of the display device are complex.

Therefore, the prior art needs to be further improved.

### SUMMARY

In view of the described deficiencies in the prior art, an objective of the present invention is to provide a display substrate and a display device, so as to overcome the defects that the all the existing Micro-LED display devices can only achieve the single-sided display, and three LED chips need to be mounted on the backplate to form a pixel unit, and therefore the workload for mass transfer of the Micro-LED display device is huge, and the circuit arrangements of the display device are complex.

A first embodiment of the present invention is a display substrate, comprising a backplate and a plurality of pixel units, wherein each pixel unit of the pixel units includes:

a white light LED disposed on the backplate and configured to emit a white light beam;

a collimating lens configured to receive the white light beam emitted by the white light LED and collimate the white light beam;

a prism layer configured to receive the white light beam collimated by the collimating lens, and reflect the white light beam in a first direction and a second direction to generate monochromatic lights of different colors in the first direction and the second direction; wherein the first direction is opposite to the second direction;

transmittance controllers disposed on the light paths of monochromatic lights of different colors generated after reflection of the prism layer, and configured to modulate the transmittance of monochromatic lights of different colors in the first direction and the second direction emitted from the prism layer; and

scattering layers disposed on the light paths of monochromatic lights of different colors modulated by the transmittance controllers, and configured to receive monochromatic lights of different colors in the first direction and the second direction modulated by the transmittance controllers, and scatter monochromatic lights of different colors in the first direction and the second direction.

The display substrate, wherein the prism layer includes a first prism group and a second prism group;

the first prism group is configured to receive the white light beam collimated by the collimating lens, and reflect the white light beam in the first direction to generate monochromatic lights of different colors in the first direction; and

the second prism group is configured to receive the white light beam collimated by the collimating lens, and reflect the white light beam in the second direction to generate monochromatic lights of different colors in the second direction.

The display substrate, wherein the transmittance controllers include a first transmittance controller group and a second transmittance controller group;

the first transmittance controller group is configured to modulate the transmittance of monochromatic lights of different colors in the first direction emitted from the first prism group; and

the second transmittance controller group is configured to modulate the transmittance of monochromatic lights of different colors in the second direction emitted from the second prism group.

The display substrate, wherein the prism layer further includes:

a reflector configured to receive the white light beam collimated by the collimating lens and reflect the white light beam along a direction parallel to the backplate to the first prism group.

The display substrate, wherein the first prism group includes a first dichroic mirror, a second dichroic mirror, and a third dichroic mirror;

the first dichroic mirror is disposed on the light path of the white light beam reflected by the reflector, and configured to receive the white light beam reflected by the reflector, and reflect a first waveband beam among the white light beam in the first direction to pass through the prism layer and enter the first transmittance controller group, and transmit other waveband beams other than the first waveband beam among the white light beam along a direction parallel to the backplate to the second dichroic mirror;

the second dichroic mirror is disposed on the light paths of the other waveband beams transmitted by the first dichroic mirror, and configured to receive the other waveband beams transmitted by the first dichroic mirror, and reflect a second waveband beam among the other waveband beams in the first direction to pass through the prism layer and enter the first transmittance controller group, and transmit remaining waveband beams other than the second waveband beam among the other waveband beams along a direction parallel to the backplate to the third dichroic mirror; and

the third dichroic mirror is disposed on the light paths of the remaining waveband beam transmitted by the second dichroic mirror, and configured to receive the remaining waveband beam transmitted by the second dichroic mirror, and reflect a third waveband beam among the remaining waveband beams in the first direction to pass through the prism layer and enter the first transmittance controller group, and transmit other waveband beams other than the third waveband beam among the remaining waveband beams along a direction parallel to the backplate to the second prism group.

The display substrate, wherein the first transmittance controller group includes: a first transmittance controller disposed on the light path of the first waveband beam reflected by the first dichroic mirror, and configured to receive the first waveband beam reflected by the first dichroic mirror, modulate the first waveband beam, and emit the modulated first waveband beam to the scattering layer;

a second transmittance controller disposed on the light path of the second waveband beam reflected by the second dichroic mirror, and configured to receive the second waveband beam reflected by the second dichroic mirror, modulate the second waveband beam, and emit the modulated second waveband beam to the scattering layer; and

a third transmittance controller disposed on the light path of the third waveband beam reflected by the third dichroic mirror, and configured to receive the third waveband beam reflected by the third dichroic mirror, modulate the third waveband beam, and emit the modulated third waveband beam to the scattering layer.

The display substrate, wherein the second prism group includes a fourth dichroic mirror, a fifth dichroic mirror, and a sixth dichroic mirror;

the fourth dichroic mirror is disposed on the light paths of other waveband beams transmitted by the third dichroic mirror, and configured to receive the other waveband beams transmitted by the third dichroic mirror, and reflect a fourth waveband beam among the other waveband beams transmitted by the third dichroic mirror in the second direction to pass through the prism layer and enter the second transmittance controller group, and transmit remaining waveband beams other than the fourth waveband beam among the other waveband beams transmitted by the third dichroic mirror along a direction parallel to the backplate to the fifth dichroic mirror;

the fifth dichroic mirror is disposed on the light paths of remaining waveband beams transmitted by the fourth dichroic mirror, and configured to receive the remaining waveband beams transmitted by the fourth dichroic mirror, and reflect a fifth waveband beam among the remaining waveband beams transmitted by the fourth dichroic mirror in the second direction to pass through the prism layer and enter the second transmittance controller group, and transmit other waveband beams other than the fifth waveband beam among the remaining waveband beams transmitted by the fourth dichroic mirror along a direction parallel to the backplate to the sixth dichroic mirror; and

the sixth dichroic mirror is disposed on the light paths of other waveband beams transmitted by the fifth dichroic mirror, and configured to receive the other waveband beams transmitted by the fifth dichroic mirror, and reflect a sixth waveband beam among the other waveband beams transmitted by the fifth dichroic mirror in the second direction to pass through the prism layer and enter the second transmittance controller group.

The display substrate, wherein the second transmittance controller group includes:

a fourth transmittance controller disposed on the light path of the fourth waveband beam reflected by the fourth dichroic mirror, and configured to receive the fourth waveband beam reflected by the fourth dichroic mirror, modulate the fourth waveband beam, and emit the modulated fourth waveband beam to the scattering layer;

a fifth transmittance controller disposed on the light path of the fifth waveband beam reflected by the fifth dichroic mirror, and configured to receive the fifth waveband beam reflected by the fifth dichroic mirror, modulate the fifth waveband beam, and emit the modulated fifth waveband beam to the scattering layer; and

a sixth transmittance controller disposed on the light path of the sixth waveband beam reflected by the sixth dichroic mirror, and configured to receive the sixth waveband beam reflected by the sixth dichroic mirror, modulate the sixth waveband beam, and emit the modulated sixth waveband beam to the scattering layer.

The display substrate, wherein the backplate includes a light transmission region and a non-light transmission region, and orthographic projection regions of the first dichroic mirror, the second dichroic mirror and the third dichroic mirror on the backplate are located in the non-light transmission region; and orthographic projection regions of the fourth dichroic mirror, the fifth dichroic mirror and the sixth dichroic mirror on the backplate are located in the light transmission region; wherein the transmittance of the light transmission region is greater than the transmittance of the non-light transmission region.

The display substrate, wherein the scattering layer is a transparent dielectric layer doped with particulates for light dispersion; the scattering layer includes a first scattering layer and a second scattering layer;

the first scattering layer is disposed on the light paths of monochromatic lights of different colors modulated by the first transmittance controller group, and configured to receive monochromatic lights of different colors modulated by the first transmittance controller group, and scatter monochromatic lights of different colors modulated by the first transmittance controller group; and

the second scattering layer is disposed on the light paths of monochromatic lights of different colors modulated by the second transmittance controller group, and configured to receive monochromatic lights of different colors modulated by the second transmittance controller group, and scatter monochromatic lights of different colors modulated by the second transmittance controller group.

A second embodiment of the present invention is a display device, at least including the described display substrate.

Regarding the beneficial effects, the present invention provides a display substrate and a display device, wherein a white light beam is reflected by a prism layer to obtain monochromatic lights of different colors in a first direction and a second direction, and monochromatic lights of different colors are modulated by transmittance controllers so as to generate corresponding colors of pixel units, achieving the double-sided display of a Micro-LED display device, increasing the functionality and interestingness of the display device, and reducing the workload for mass transfer of the Micro-LED display device and the complexity of circuit arrangements of the display device.

### BRIEF DESCRIPTION OF THE DRAWINGS

FIG. 1 is a schematic diagram showing the structure of an existing display substrate using LEDs of RGB three colors as a pixel unit;

FIG. 2 is a partially enlarged view of the existing display substrate using LEDs of RGB three colors as a pixel unit;

FIG. 3 is a schematic diagram showing the structure of an existing display substrate using blue light LEDs as a pixel unit;

FIG. 4 is a schematic diagram showing the structure of a display substrate provided in a first embodiment of the present invention; and

FIG. 5 is a schematic diagram showing the structure of a display substrate provided in a second embodiment of the present invention.

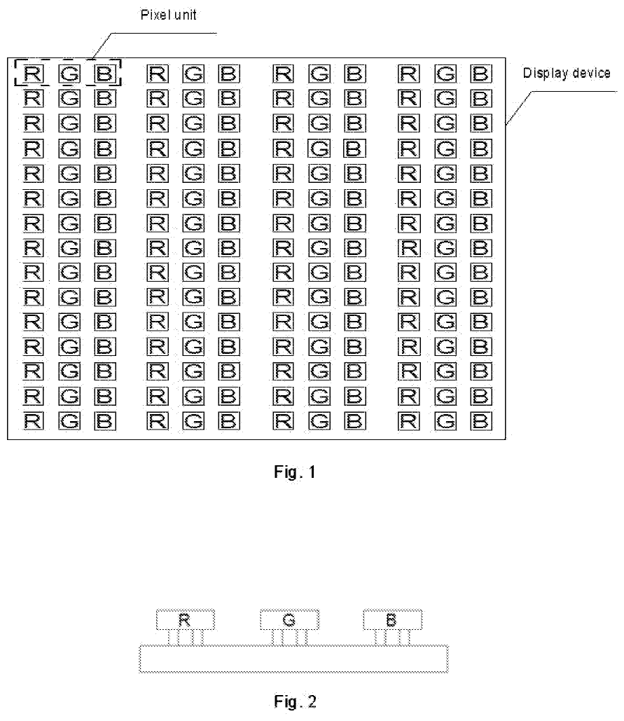

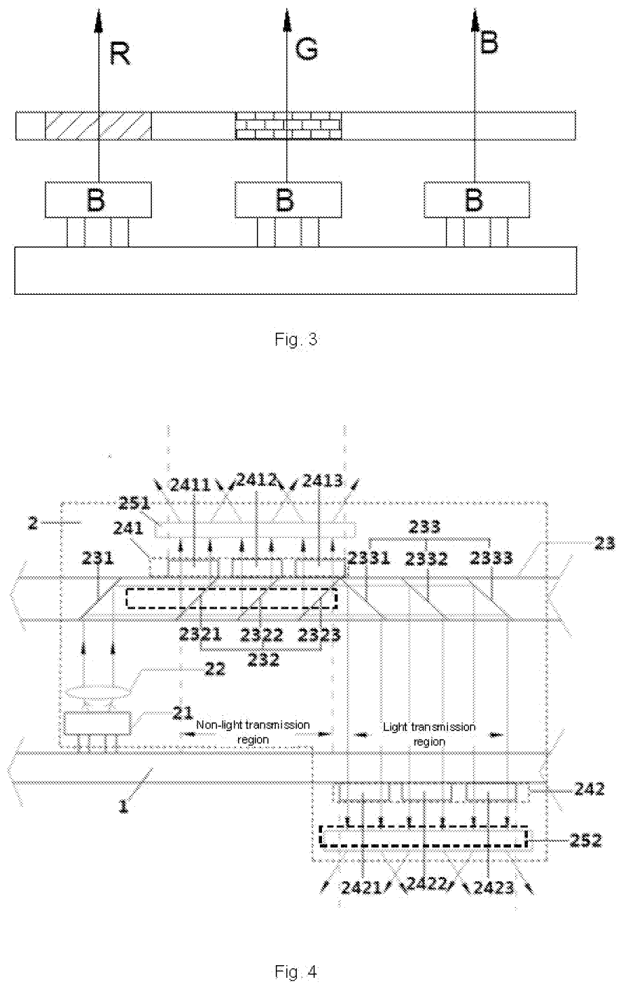

### DETAILED DESCRIPTION OF THE EMBODIMENTS

To make the objective, technical solutions, and advantages of the present invention more explicit and clearer, the present invention is further described in detail below with reference to the drawings and embodiments. It should be understood that the embodiments described herein are only intended to explain the present invention, but not to limit the present invention.

As all the existing Micro-LED display devices can only achieve the single-sided display, and three LED chips need to be mounted on the backplate to form a pixel unit, the defects that the workload for mass transfer of the Micro-LED display device is huge, and the circuit arrangements of the display device are complex exist. In order to solve the problems above, Embodiment I of the present invention provides a display substrate, as shown in FIG. 4. The display substrate includes a backplate 1 and a plurality of pixel units 2. Each pixel unit 2 of the pixel units include a white light LED 21 disposed on the backplate 1 and configured to emit a white light beam; a collimating lens 22 configured to receive the white light beam emitted by the white light LED 21 and collimate the white light beam; a prism layer 23 configured to receive the white light beam collimated by the collimating lens 22, and reflect the white light beam in a first direction and a second direction to generate monochromatic lights of different colors in the first direction and the second direction, wherein the first direction is opposite to the second direction; transmittance controllers disposed on the light paths of monochromatic lights of different colors generated after reflection of the prism layer 23, and configured to modulate the transmittance of monochromatic lights of different colors in the first direction and the second direction emitted from the prism layer 23; and scattering layers disposed on the light paths of monochromatic lights of different colors modulated by the transmittance controllers, and configured to receive monochromatic lights of different colors in the first direction and the second direction modulated by the transmittance controllers, and scatter monochromatic lights of different colors in the first direction and the second direction. When in a specific implementation, the white light beam emitted by the white light LED 21 is a mixed beam containing the wavebands of three colors, i.e. red, green and blue, the white light beam is collimated by the collimating lens 22 and irradiated onto the prism layer 23, and the white light beam when passing through the prism layer 23 is reflected as monochromatic lights of different colors in a first direction and a second direction which are opposite to each other as light of different wavelengths has different refractive indexes when passing through the prism layer 23, so as to achieve the RGB three-color display in the first direction and the second direction, thereby achieving the double-sided display of the Micro-LED display device. Furthermore, the RGB three-color display can be achieved merely by one white light LED 21, thus greatly reducing the workload for mass transfer of the Micro-LED display device, and the complexity of circuit arrangements of the display device.

In a specific embodiment, as the white light beam emitted by the white light LED 21 is divergent light, in order to enable the white light beam emitted by the white light LED 21 to be collimated and irradiated onto the prism layer 23, a collimating lens 22 is provided between the white light LED 21 and the prism layer 23 in this embodiment, and the collimating lens 22 is configured to receive the white light beam emitted by the white light LED 21 and collimate the white light beam.

In a specific embodiment, the prism layer includes a first prism group 232 and a second prism group 233. The first prism group 232 is configured to receive the white light beam collimated by the collimating lens 22, and reflect the white light beam in the first direction to generate monochromatic lights of different colors in the first direction; and the second prism group 233 is configured to receive the white light beam collimated by the collimating lens 22, and reflect the white light beam in the second direction to generate monochromatic lights of different colors in the second direction. When in a specific implementation, the white light beam collimated by the collimating lens 22 is reflected by the first prism group 232 and the second prism group 233 to generate monochromatic lights of different colors in the first direction and the second direction.

In a specific embodiment, the transmittance controllers include a first transmittance controller group 241 and a second transmittance controller group 242. The first transmittance controller group 241 is configured to modulate the transmittance of monochromatic lights of different colors in the first direction emitted from the first prism group 232; and the second transmittance controller group 242 is configured to modulate the transmittance of monochromatic lights of different colors in the second direction emitted from the second prism group 233.

In a specific embodiment, the prism layer 23 further includes a reflector 231, and the reflector 231 is configured to receive the white light beam collimated by the collimating lens 22 and reflect the collimated white light beam along a direction parallel to the backplate 1 to the first prism group 232. The first prism group 232 of the prism layer 23 includes a first dichroic mirror 2321, a second dichroic mirror 2322 and a third dichroic mirror 2323. The first dichroic mirror 2321 is disposed on the light path of the white light beam reflected by the reflector 231, and configured to receive the white light beam reflected by the reflector 231, and reflect a first waveband beam among the white light beam in the first direction to pass through the prism layer 23 and enter the first transmittance controller group 241, and transmit other waveband beams other than the first waveband beam among the white light beam along a direction parallel to the backplate 1 to the second dichroic mirror 2322. The second dichroic mirror 2322 is disposed on the light paths of the other waveband beams transmitted by the first dichroic mirror 2321, and configured to receive the other waveband beams transmitted by the first dichroic mirror 2321, and reflect a second waveband beam among the other waveband beams in the first direction to pass through the prism layer 23 and enter the first transmittance controller group 241, and transmit remaining waveband beams other than the second waveband beam among the other waveband beams along a direction parallel to the backplate 1 to the third dichroic mirror 2323. The third dichroic mirror 2323 is disposed on the light paths of the other waveband beam transmitted by the second dichroic mirror 2322, and configured to receive the remaining waveband beams transmitted by the second dichroic mirror 2322, and reflect a third waveband beam among the remaining waveband beams in the first direction to pass through the prism layer 23 and enter the first transmittance controller group 241, and transmit other waveband beams other than the third waveband beam among the remaining waveband beams along a direction parallel to the backplate 1 to the second prism group 233. When in a specific implementation, the white light beam reflected by the reflector 231 is reflected by the first prism group 232, i.e. the first dichroic mirror 2321, the second dichroic mirror 2322 and the third dichroic mirror 2323 to obtain a first waveband beam, a second waveband beam and a third waveband beam in the first direction, respectively.

When in a specific implementation, the first waveband beam, the second waveband beam and the third waveband beam are beams of wavebands of different colors and are respectively one of a red light waveband beam, a green light waveband beam and a blue light waveband beam. Namely, the first waveband beam is a red light waveband beam, the second waveband beam is a green light waveband beam, and the third waveband beam is a blue light waveband beam; or the first waveband beam is a green light waveband beam, the second waveband beam is a blue light waveband beam, and the third waveband beam is a red light waveband beam; or the first waveband beam is a blue light waveband beam, the second waveband beam is a red light waveband beam, and the third waveband beam is a green light waveband beam, so that the RGB three-color display is achieved in the first direction by one white light LED.

In a specific embodiment, the first transmittance controller group 241 includes a first transmittance controller 2411, a second transmittance controller 2412 and a third transmittance controller 2413. The first transmittance controller 2411, the second transmittance controller 2412, and the third transmittance controller 2413 are provided corresponding to the first dichroic mirror 2321, the second dichroic mirror 2322, and the third dichroic mirror 2323, respectively. The first transmittance controller 2411 is disposed on the light path of the first waveband beam reflected by the first dichroic mirror 2321, and configured to receive the first waveband beam reflected by the first dichroic mirror 2321, modulate the first waveband beam, and emit the modulated first waveband beam to the scattering layer. The second transmittance controller 2412 is disposed on the light path of the second waveband beam reflected by the second dichroic mirror 2322, and configured to receive the second waveband beam reflected by the second dichroic mirror 2322, modulate the second waveband beam, and emit the modulated second waveband beam to the scattering layer. The third transmittance controller 2413 is disposed on the light path of the third waveband beam reflected by the third dichroic mirror 2323, and configured to receive the third waveband beam reflected by the third dichroic mirror 2323, modulate the third waveband beam, and emit the modulated third waveband beam to the scattering layer.

When in a specific implementation, the second prism group 233 of the prism layer 23 includes a fourth dichroic mirror 2331, a fifth dichroic mirror 2332 and a sixth dichroic mirror 2333. The fourth dichroic mirror 2331 is disposed on the light paths of other waveband beams transmitted by the third dichroic mirror 2323, and configured to receive the other waveband beams transmitted by the third dichroic mirror 2323, and reflect a fourth waveband beam among the other waveband beams transmitted by the third dichroic mirror 2323 in the second direction to pass through the prism layer 23 and enter the second transmittance controller group 242, and transmit remaining waveband beams other than the fourth waveband beam among the other waveband beams transmitted by the third dichroic mirror 2323 along a direction parallel to the backplate 1 to the fifth dichroic mirror 2332. The fifth dichroic mirror 2332 is disposed on the light paths of other waveband beams transmitted by the fourth dichroic mirror 2331, and configured to receive the remaining waveband beams transmitted by the fourth dichroic mirror 2331, and reflect a fifth waveband beam among the remaining waveband beams transmitted by the fourth dichroic mirror 2331 in the second direction to pass through the prism layer 23 and enter the second transmittance controller group 242, and transmit other waveband beams other than the fifth waveband beam among the remaining waveband beams transmitted by the fourth dichroic mirror 2331 along a direction parallel to the backplate 1 to the sixth dichroic mirror 2333. The sixth dichroic mirror 2333 is disposed on the light paths of other waveband beams transmitted by the fifth dichroic mirror 2332, and configured to receive the other waveband beams transmitted by the fifth dichroic mirror 2332, and reflect a sixth waveband beam among the other waveband beams transmitted by the fifth dichroic mirror 2332 in the second direction to pass through the prism layer 23 and enter the second transmittance controller group 242. When in a specific implementation, the white light beam reflected by the reflector 231 is reflected by the second prism group 233, i.e. the fourth dichroic mirror 2331, the fifth dichroic mirror 2332 and the sixth dichroic mirror 2333 to obtain a fourth waveband beam, a fifth waveband beam and a sixth waveband beam in the second direction, respectively.

When in a specific implementation, the fourth waveband beam, the fifth waveband beam and the sixth waveband beam are beams of wavebands of different colors and are respectively one of a red light waveband beam, a green light waveband beam and a blue light waveband beam. Namely, the fourth waveband beam is a red light waveband beam, the fifth waveband beam is a green light waveband beam, and the sixth waveband beam is a blue light waveband beam; or the fourth waveband beam is a green light waveband beam, the fifth waveband beam is a blue light waveband beam, and the sixth waveband beam is a red light waveband beam; or the fourth waveband beam is a blue light waveband beam, the fifth waveband beam is a red light waveband beam, and the sixth waveband beam is a green light waveband beam. By one white light LED 21, the RGB three-color display is achieved in the first direction and the RGB three-color display is also achieved in the second direction, thereby achieving the double-sided display of the Micro-LED display device. In a specific embodiment, among the first waveband beam, the second waveband beam and the third waveband beam, the wavelength of a red light waveband beam is 630-650 nm, the wavelength of a green light waveband beam is 500-520 nm, and the wavelength of a blue light waveband beam is 460-470 nm. Among the fourth waveband beam, the fifth waveband beam and the sixth waveband beam, the wavelength of a red light waveband beam is 650-670 nm, the wavelength of a green light waveband beam is 520-550 nm, and the wavelength of a blue light waveband beam is 470-480 nm.

In a specific embodiment, corresponding to the fourth dichroic mirror 2331, the fifth dichroic mirror 2332 and the sixth dichroic mirror 2333, the second transmittance controller group 242 includes a fourth transmittance controller 2421, a fifth transmittance controller 2422 and a sixth transmittance controller 2423. The fourth transmittance controller 2421 is disposed on the light path of the fourth waveband beam reflected by the fourth dichroic mirror 2331, and configured to receive the fourth waveband beam reflected by the fourth dichroic mirror 2331, modulate the fourth waveband beam, and emit the modulated fourth waveband beam to the scattering layer. The fifth transmittance controller 2422 is disposed on the light path of the fifth waveband beam reflected by the fifth dichroic mirror 2332, and configured to receive the fifth waveband beam reflected by the fifth dichroic mirror 2332, modulate the fifth waveband beam, and emit the modulated fifth waveband beam to the scattering layer. The sixth transmittance controller 2423 is disposed on the light path of the sixth waveband beam reflected by the sixth dichroic mirror 2333, and configured to receive the sixth waveband beam reflected by the sixth dichroic mirror 2333, modulate the sixth waveband beam, and emit the modulated sixth waveband beam to the scattering layer.

When in a specific implementation, Embodiment 1 is merely a specific implementation of the present invention. In the present invention, positions of the first dichroic mirror 2321, the second dichroic mirror 2322, the third dichroic mirror 2323, the fourth dichroic mirror 2331, the fifth dichroic mirror 2332 and the sixth dichroic mirror 2333 can be arbitrarily changed.

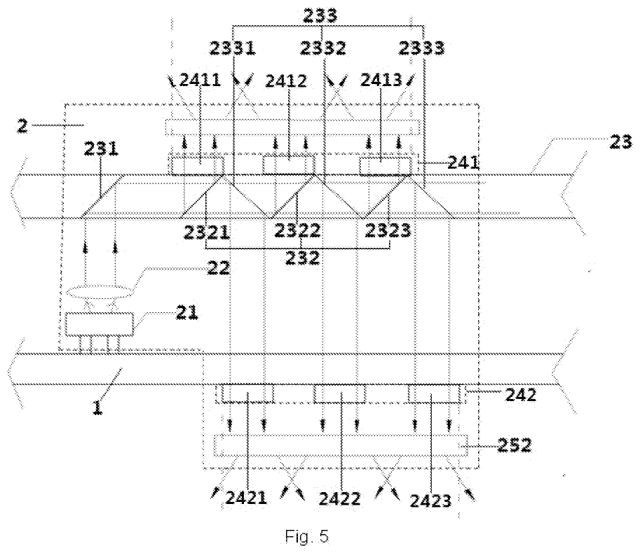

A second embodiment of the present invention provides a schematic diagram showing the structure of a display substrate, as shown in FIG. 5. In this embodiment, the first dichroic mirror 2321, the fourth dichroic mirror 2331, the second dichroic mirror 2322, the fifth dichroic mirror 2332, the third dichroic mirror 2323, and the sixth dichroic mirror 2333 are adjacently arranged in sequence. In the second embodiment of the present invention, the first dichroic mirror 2321 is disposed on the light path of the white light beam reflected by the reflector 231, and configured to receive the white light beam reflected by the reflector 231, and reflect a first waveband beam among the white light beam in the first direction to pass through the prism layer 23 and enter the first transmittance controller group 241, and transmit other waveband beams other than the first waveband beam among the white light beam along a direction parallel to the backplate 1 to the fourth dichroic mirror 2331; the second dichroic mirror 2322 is disposed on the light paths of the remaining waveband beam transmitted by the fourth dichroic mirror 2331, and configured to receive the remaining waveband beams transmitted by the fourth dichroic mirror 2331, and reflect a second waveband beam among the remaining waveband beams in the first direction to pass through the prism layer 23 and enter the first transmittance controller group 241, and transmit other waveband beams other than the second waveband beam among the remaining waveband beams along a direction parallel to the backplate 1 to the fifth dichroic mirror 2332; the third dichroic mirror 2323 is disposed on the light paths of the remaining waveband beam transmitted by the fifth dichroic mirror 2332, and configured to receive the remaining waveband beam transmitted by the fifth dichroic mirror 2332, and reflect a third waveband beam among the remaining waveband beams in the first direction to pass through the prism layer 23 and enter the first transmittance controller group 241, and transmit other waveband beams other than the third waveband beam among the remaining waveband beams along a direction parallel to the backplate 1 to the sixth dichroic mirror 2333; the fourth dichroic mirror 2331 is disposed on the light paths of the other waveband beams transmitted by the first dichroic mirror 2321, and configured to receive the other waveband beams transmitted by the first dichroic mirror 2321, and reflect a fourth waveband beam among the other waveband beams transmitted by the first dichroic mirror 2321 in the second direction to pass through the prism layer 23 and enter the second transmittance controller group 242, and transmit remaining waveband beams other than the fourth waveband beam among the other waveband beams transmitted by the first dichroic mirror 2321 along a direction parallel to the backplate 1 to the second dichroic mirror 2322; the fifth dichroic mirror 2332 is disposed on the light paths of other waveband beams transmitted by the second dichroic mirror 2322, and configured to receive the other waveband beams transmitted by the second dichroic mirror 2322, and reflect a fifth waveband beam among the other waveband beams transmitted by the second dichroic mirror 2322 in the second direction to pass through the prism layer 23 and enter the second transmittance controller group 242, and transmit remaining waveband beams other than the fifth waveband beam among the other waveband beams transmitted by the second dichroic mirror 2322 along a direction parallel to the backplate 1 to the third dichroic mirror 2323; and the sixth dichroic mirror 2333 is disposed on the light paths of other waveband beams transmitted by the third dichroic mirror 2323, and configured to receive the other waveband beams transmitted by the third dichroic mirror 2323, and reflect a sixth waveband beam among the other waveband beams transmitted by the third dichroic mirror 2323 in the second direction to pass through the prism layer 23 and enter the second transmittance controller group 242.

When in a specific implementation, the white light beam reflected by the reflector 231 is reflected to the first dichroic mirror 2321 by the reflector 231 along a direction parallel to the backplate 1 and towards the first dichroic mirror 2321, and the first dichroic mirror 2321, upon receiving the white light beam reflected by the reflector 231, reflects the first waveband beam along the first direction perpendicular to the backplate 1 to pass through the prism layer 23 and enter the first transmittance controller group 241, and transmits other waveband beams other than the first waveband beam among the white light beam along a direction parallel to the backplate 1 and towards the fourth dichroic mirror 2331. The fourth dichroic mirror 2331 receives the beams transmitted by the first dichroic mirror 2321, and reflects the fourth waveband beam along the second direction perpendicular to the backplate 1 to pass through the prism layer 23 and enter the second transmittance controller group 242, and transmits other waveband beams other than the fourth waveband beam among said beams along a direction parallel to the backplate 1 and towards the second dichroic mirror 2322. Thereafter, the second dichroic mirror 2322 receives the beams transmitted by the fourth dichroic mirror 2331, and reflects the second waveband beam along the first direction perpendicular to the backplate 1 to pass through the prism layer 23 and enter the first transmittance controller group 241, and transmits other waveband beams other than the second waveband beam among said beams along a direction parallel to the backplate 1 and towards the fifth dichroic mirror 2332. The fifth dichroic mirror 2332 receives the beams transmitted by the second dichroic mirror 2322, reflects the fifth waveband beam along the second direction perpendicular to the backplate 1 to pass through the prism layer 23 and enter the second transmittance controller group 242, and transmits other waveband beams other than the second waveband beam among said beams along a direction parallel to the backplate 1 and towards the third dichroic mirror 2323. The third dichroic mirror 2323 receives the beams transmitted by the fifth dichroic mirror 2332, reflects the third waveband beam along the first direction perpendicular to the backplate 1 to pass through the prism layer 23 and enter the first transmittance controller group 241, and transmits other waveband beams other than the second waveband beam among said beams along a direction parallel to the backplate 1 and towards the sixth dichroic mirror 2333. Finally, the sixth dichroic mirror 2333 receives the beams transmitted by the third dichroic mirror 2323, reflects the sixth waveband beam along the second direction perpendicular to the backplate 1 to pass through the prism layer 23 and enter the second transmittance controller group 242, thereby achieving the double-sided display of the Micro-LED display device in the first direction and the second direction perpendicular to the backplate 1.

Of course, Embodiment 1 and Embodiment 2 of the present invention are merely two arrangement methods of the first dichroic mirror 2321, the second dichroic mirror 2322, the third dichroic mirror 2323, the fourth dichroic mirror 2331, the fifth dichroic mirror 2332 and the sixth dichroic mirror 2333. It can be seen from Embodiment 1 and Embodiment 2 of the present invention that, as long as the first dichroic mirror 2321, the second dichroic mirror 2322 and the third dichroic mirror 2323 reflect light of RGB three colors in the first direction, and the fourth dichroic mirror 2331, the fifth dichroic mirror 2332 and the sixth dichroic mirror 2333 reflect light of RGB three colors in the second direction opposite to the first direction, the double-sided display of the Micro-LED display device can be achieved. Therefore, any change in the positions of the first dichroic mirror 2321, the second dichroic mirror 2322, the third dichroic mirror 2323, the fourth dichroic mirror 2331, the fifth dichroic mirror 2332 and the sixth dichroic mirror 2333 will come into the scope of protection of the present invention.

In a specific embodiment, the backplate 1 includes a light transmission region and a non-light transmission region, and orthographic projections of the first dichroic mirror, the second dichroic mirror and the third dichroic mirror on the backplate are located in the non-light transmission region; and orthographic projection regions of the fourth dichroic mirror, the fifth dichroic mirror and the sixth dichroic mirror on the backplate are located in the light transmission region, and the transmittance of the light transmission region is greater than the transmittance of the non-light transmission region.

In a specific embodiment, as the monochromatic lights of different colors modulated by the transmittance controllers have collimation which is adverse to the display effect of the display device, the pixel unit 2 in this embodiment further includes scattering layers. The scattering layers are configured to receive monochromatic lights of different colors modulated by the transmittance controllers, and scatter monochromatic lights of different colors, thereby expanding the display range of the Micro-LED display device. Specifically, the scattering layers include a first scattering layer 251 and a second scattering layer 252; the first scattering layer 251 is disposed on the light paths of monochromatic lights of different colors modulated by the first transmittance controller group 241, and configured to receive monochromatic lights of different colors modulated by the first transmittance controller group 241, and scatter monochromatic lights of different colors modulated by the first transmittance controller group 241; and the second scattering layer 252 is disposed on the light paths of monochromatic lights of different colors modulated by the second transmittance controller group 242, and configured to receive monochromatic lights of different colors modulated by the second transmittance controller group 242, and scatter monochromatic lights of different colors modulated by the second transmittance controller group 242. The scattering layer may be a transparent dielectric layer doped with particulates for light dispersion. The transparent dielectric layer is a transparent adhesive layer, and the particulates for light dispersion range from tens of nanometers to several microns in size, and may be organic particles or inorganic particles. If the particulates for light dispersion are organic particles, the organic particles may include multi-layered and multi-component particles prepared from a particle layer and monomers of another type overlying the particle layer, and the particle layer includes one or more of a homopolymer or copolymer of acrylic particles such as methyl methacrylate or 2-ethylhexyl acrylate, and copolymers and homopolymers of olefin-based particles such as polyethylene, and acrylic and olefin-based particles. If the particulates for light dispersion are inorganic particles, the inorganic particles may include one or more of silicon oxide, aluminum oxide, titanium oxide, zirconium oxide, and magnesium fluoride.

In a specific embodiment, the first transmittance controller 2411, the second transmittance controller 2412 and the third transmittance controller 2413 are provided between the first prism group 232 and the first scattering layer 251. The fourth transmittance controller 2421, the fifth transmittance controller 2422 and the sixth transmittance controller 2423 may be disposed between the second prism group 233 and the backplate 1 or disposed between the backplate 1 and the second scattering layer 252. When the fourth transmittance controller 2421, the fifth transmittance controller 2422 and the sixth transmittance controller 2423 are disposed between the second prism group 233 and the backplate 1, the light of RGB three colors reflected by the second prism group 233 along the second direction perpendicular to the backplate 1 is modulated by the fourth transmittance controller 2421, the fifth transmittance controller 2422 and the sixth transmittance controller 2423 and then passes through the backplate 1 and is irradiated onto the second scattering layer 252 for scattering. When the fourth transmittance controller 2421, the fifth transmittance controller 2422 and the sixth transmittance controller 2423 are disposed between the backplate 1 and the second scattering layer 252, the light of RGB three colors reflected by the second prism group 233 along the second direction perpendicular to the backplate 1 passes through the backplate 1 and then is modulated by the fourth transmittance controller 2421, the fifth transmittance controller 2422 and the sixth transmittance controller 2423.

In summary, the present invention provides a display substrate and a display device. The display substrate includes a backplate and a plurality of pixel units; each pixel unit of the pixel units each include a white light LED configured to emit a white light beam; a collimating lens configured to receive the white light beam and collimate the white light beam; a collimating len configured to reflect the white light beam collimated by the collimating lens in a first direction and a second direction to generate monochromatic lights of different colors in the first direction and the second direction; transmittance controller configured to modulate the transmittance of monochromatic lights of different colors in the first direction and the second direction; and scattering layers configured to scatter monochromatic lights of different colors in the first direction and the second direction modulated by the transmittance controllers. In the present application, a white light beam is emitted by a white light LED, the white light beam is collimated by a collimating lens and reflected by a prism layer to obtain monochromatic lights of different colors in a first direction and a second direction, achieving the double-sided display of a Micro-LED display device, increasing the functionality and interestingness of the display device, and reducing the workload for mass transfer of the Micro-LED display device and the complexity of circuit arrangements of the display device.

It should be understood that the systemic application of the present invention is not limited to the examples above, and those skilled in the art can make improvements or modifications according to the above descriptions, and all these improvements and modifications shall belong to the scope of protection of the appended claims of the present invention.

What is claimed is:

1. A display substrate, comprising a backplate and a plurality of pixel units, wherein each pixel unit of the pixel units comprises:
a white light LED disposed on the backplate and configured to emit a white light beam;
a collimating lens configured to receive the white light beam emitted by the white light LED and collimate the white light beam;
a prism layer configured to receive the white light beam collimated by the collimating lens, and reflect the white light beam in a first direction and a second direction to generate monochromatic lights of different colors in the first direction and the second direction; wherein the first direction is opposite to the second direction;
transmittance controllers disposed on the light paths of monochromatic lights of different colors generated after reflection of the prism layer, and configured to modulate the transmittance of monochromatic lights of different colors in the first direction and the second direction emitted from the prism layer; and
scattering layers disposed on the light paths of monochromatic lights of different colors modulated by the transmittance controllers, and configured to receive monochromatic lights of different colors in the first direction and the second direction modulated by the transmittance controllers, and scatter monochromatic lights of different colors in the first direction and the second direction.

2. The display substrate according to claim 1, wherein the prism layer comprises a first prism group and a second prism group;
the first prism group is configured to receive the white light beam collimated by the collimating lens, and reflect the white light beam in the first direction to generate monochromatic lights of different colors in the first direction; and
the second prism group is configured to receive the white light beam collimated by the collimating lens, and reflect the white light beam in the second direction to generate monochromatic lights of different colors in the second direction.

3. The display substrate according to claim 2, wherein the transmittance controllers comprise a first transmittance controller group and a second transmittance controller group;
the first transmittance controller group is configured to modulate the transmittance of monochromatic lights of different colors in the first direction emitted from the first prism group; and
the second transmittance controller group is configured to modulate the transmittance of monochromatic lights of different colors in the second direction emitted from the second prism group.

4. The display substrate according to claim 3, wherein the prism layer further comprises:
a reflector configured to receive the white light beam collimated by the collimating lens and reflect the white light beam along a direction parallel to the backplate to the first prism group.

5. The display substrate according to claim 4, wherein the first prism group comprises a first dichroic mirror, a second dichroic mirror, and a third dichroic mirror;
the first dichroic mirror is disposed on the light path of the white light beam reflected by the reflector, and configured to receive the white light beam reflected by the reflector, and reflect a first waveband beam among the white light beam in the first direction to pass through the prism layer and enter the first transmittance controller group, and transmit other waveband beams other than the first waveband beam among the white light beam along a direction parallel to the backplate to the second dichroic mirror;
the second dichroic mirror is disposed on the light paths of the other waveband beams transmitted by the first dichroic mirror, and configured to receive the other waveband beams transmitted by the first dichroic mirror, and reflect a second waveband beam among the other waveband beams in the first direction to pass through the prism layer and enter the first transmittance controller group, and transmit remaining waveband beams other than the second waveband beam among the other waveband beams along a direction parallel to the backplate to the third dichroic mirror; and
the third dichroic mirror is disposed on the light paths of the remaining waveband beam transmitted by the second dichroic mirror, and configured to receive the remaining waveband beam transmitted by the second dichroic mirror, and reflect a third waveband beam among the remaining waveband beams in the first direction to pass through the prism layer and enter the first transmittance controller group, and transmit other waveband beams other than the third waveband beam among the remaining waveband beams along a direction parallel to the backplate to the second prism group.

6. The display substrate according to claim 5, wherein the first transmittance controller group comprises:
a first transmittance controller disposed on the light path of the first waveband beam reflected by the first dichroic mirror, and configured to receive the first waveband beam reflected by the first dichroic mirror, modulate the first waveband beam, and emit the modulated first waveband beam to the scattering layer;
a second transmittance controller disposed on the light path of the second waveband beam reflected by the second dichroic mirror, and configured to receive the second waveband beam reflected by the second dichroic mirror, modulate the second waveband beam, and emit the modulated second waveband beam to the scattering layer; and
a third transmittance controller disposed on the light path of the third waveband beam reflected by the third dichroic mirror, and configured to receive the third waveband beam reflected by the third dichroic mirror, modulate the third waveband beam, and emit the modulated third waveband beam to the scattering layer.

7. The display substrate according to claim 5, wherein the second prism group comprises a fourth dichroic mirror, a fifth dichroic mirror, and a sixth dichroic mirror;
the fourth dichroic mirror is disposed on the light paths of other waveband beams transmitted by the third dichroic mirror, configured to receive the other waveband beams transmitted by the third dichroic mirror, and reflect a fourth waveband beam among the other waveband beams transmitted by the third dichroic mirror in the second direction to pass through the prism layer and enter the second transmittance controller group, and transmit remaining waveband beams other than the fourth waveband beam among the other waveband beams transmitted by the third dichroic mirror along a direction parallel to the backplate to the fifth dichroic mirror;
the fifth dichroic mirror is disposed on the light paths of remaining waveband beams transmitted by the fourth dichroic mirror, and configured to receive the remaining waveband beams transmitted by the fourth dichroic mirror, and reflect a fifth waveband beam among the remaining waveband beams transmitted by the fourth dichroic mirror in the second direction to pass through the prism layer and enter the second transmittance controller group, and transmit other waveband beams other than the fifth waveband beam among the remaining waveband beams transmitted by the fourth dichroic mirror along a direction parallel to the backplate to the sixth dichroic mirror; and
the sixth dichroic mirror is disposed on the light paths of other waveband beams transmitted by the fifth dichroic mirror, and configured to receive the other waveband beams transmitted by the fifth dichroic mirror, and reflect a sixth waveband beam among the other waveband beams transmitted by the fifth dichroic mirror in the second direction to pass through the prism layer and enter the second transmittance controller group.

8. The display substrate according to claim 7, wherein the second transmittance controller group comprises:
a fourth transmittance controller disposed on the light path of the fourth waveband beam reflected by the fourth dichroic mirror, and configured to receive the fourth waveband beam reflected by the fourth dichroic mirror, modulate the fourth waveband beam, and emit the modulated fourth waveband beam to the scattering layer;
a fifth transmittance controller disposed on the light path of the fifth waveband beam reflected by the fifth dichroic mirror, and configured to receive the fifth waveband beam reflected by the fifth dichroic mirror, modulate the fifth waveband beam, and emit the modulated fifth waveband beam to the scattering layer; and
a sixth transmittance controller disposed on the light path of the sixth waveband beam reflected by the sixth dichroic mirror, and configured to receive the sixth waveband beam reflected by the sixth dichroic mirror, modulate the sixth waveband beam, and emit the modulated sixth waveband beam to the scattering layer.

9. The display substrate according to claim 8, wherein the backplate comprises a light transmission region and a non-light transmission region, and orthographic projection regions of the first dichroic mirror, the second dichroic mirror and the third dichroic mirror on the backplate are located in the non-light transmission region; and orthographic projection regions of the fourth dichroic mirror, the fifth dichroic mirror and the sixth dichroic mirror on the backplate are located in the light transmission region; wherein the transmittance of the light transmission region is greater than the transmittance of the non-light transmission region.

10. The display substrate according to claim 8, wherein the scattering layer is a transparent dielectric layer doped with particulates for light dispersion; the scattering layer comprises a first scattering layer and a second scattering layer;
the first scattering layer is disposed on the light paths of monochromatic lights of different colors modulated by the first transmittance controller group, and configured to receive monochromatic lights of different colors modulated by the first transmittance controller group, and scatter monochromatic lights of different colors modulated by the first transmittance controller group; and
the second scattering layer is disposed on the light paths of monochromatic lights of different colors modulated by the second transmittance controller group, and configured to receive monochromatic lights of different colors modulated by the second transmittance controller group, and scatter monochromatic lights of different colors modulated by the second transmittance controller group.

11. A display device, at least comprising a display substrate, and the display substrate comprising a backplate and a plurality of pixel units, wherein each pixel unit of the pixel units comprises:
a white light LED disposed on the backplate and configured to emit a white light beam;
a collimating lens configured to receive the white light beam emitted by the white light LED and collimate the white light beam;
a prism layer configured to receive the white light beam collimated by the collimating lens, and reflect the white light beam in a first direction and a second direction to generate monochromatic lights of different colors in the first direction and the second direction; wherein the first direction is opposite to the second direction;
transmittance controllers disposed on the light paths of monochromatic lights of different colors generated after reflection of the prism layer, and configured to modulate the transmittance of monochromatic lights of different colors in the first direction and the second direction emitted from the prism layer; and
scattering layers disposed on the light paths of monochromatic lights of different colors modulated by the transmittance controllers, and configured to receive monochromatic lights of different colors in the first direction and the second direction modulated by the transmittance controllers, and scatter monochromatic lights of different colors in the first direction and the second direction.

12. The display substrate according to claim 9, wherein the scattering layer is a transparent dielectric layer doped with particulates for light dispersion; the scattering layer comprises a first scattering layer and a second scattering layer;
the first scattering layer is disposed on the light paths of monochromatic lights of different colors modulated by the first transmittance controller group, and configured to receive monochromatic lights of different colors modulated by the first transmittance controller group, and scatter monochromatic lights of different colors modulated by the first transmittance controller group; and
the second scattering layer is disposed on the light paths of monochromatic lights of different colors modulated by the second transmittance controller group, and configured to receive monochromatic lights of different colors modulated by the second transmittance controller group, and scatter monochromatic lights of different colors modulated by the second transmittance controller group.
